(19) United States
(12) Patent Application Publication
(10) Pub. No.: US 2009/0026924 A1
(43) Pub. Date: Jan. 29, 2009

(54) METHODS OF MAKING LOW-REFRACTIVE INDEX AND/OR LOW-K ORGANOSILICATE COATINGS

(76) Inventors: Roger Y. Leung, San Jose, CA (US); De-Ling Zhou, Sunnyvale, CA (US); Wenya Fan, Campbell, CA (US); Peter A. Smith, Long Valley, NJ (US); Paul G. Apen, Scottsdale, AZ (US); Brian J. Daniels, La Honda, CA (US); Ananth Naman, Naperville, IL (US); Teresa A. Ramos, San Jose, CA (US); Robert R. Roth, Sunnyvale, CA (US)

Correspondence Address: SCOTT D. JACOBSON;Honeywell International Inc. - Patent Department, 101 Columbia Road, Morristown, NJ, 07962, US

(21) Appl. No.: 11/931,088

(22) Filed: Oct. 31, 2007

Related U.S. Application Data
(60) Provisional application No. 60/951,250, filed on Jul. 23, 2007.

(51) Int. Cl. H01L 51/54; H01L 33/00; B32B 3/26; B05D 5/06; H01L 27/15

(52) U.S. Cl. 313/504; 427/164; 428/304.4; 257/98; 257/88; 257/E33.06; 977/834; 977/900

(57) ABSTRACT

A method for forming a substantially transparent nanoporous organosilicate film on a substantially transparent substrate, for use in optical lighting devices such as organic light emitting diodes (OLEDs). The method includes first preparing a composition comprising a silicon containing pre-polymer, a porogen, and a catalyst. The composition is coated onto a substrate which is substantially transparent to visible light, forming a film thereon. The film is then gelled by crosslinking and cured by heating, such that the resulting cured film is substantially transparent to visible light. It is preferred that both the substrate and the nanoporous film are at least 98% transparent to visible light. Optical devices which include the resulting structures of this invention exhibit improved light extraction and illuminance where the nanoporous organosilicate film has a low refractive index in the range of 1.05 to 1.4, serving as an impedance matching layer in such devices.

### CROSS REFERENCE TO RELATED APPLICATIONS

This application claims the benefit of U.S. provisional application Ser. No. 60/951,250 filed on Jul. 23, 2007, which is incorporated herein by reference.

### BACKGROUND OF THE INVENTION

1. Field of the Invention

The present invention relates to the formation of optical devices. Particularly, the invention relates to optical lighting devices comprising a structure which includes a substantially transparent nanoporous organosilicate film on a substantially transparent substrate, and a method for making the same. It is preferred that both the substrate and the nanoporous film are at least 98% transparent to visible light.

2. Description of the Related Art

It is known in the art to produce light-emitting or light-transmitting optical electronic devices, such as light emitting diodes (LEDs), organic light emitting devices (OLEDs), photonic bandgap devices, and polarizers. Light extraction from a multilayered optical device such as an OLED is limited by total internal reflection (TIR) occurring at several planar interfaces. A typical OLED includes several planar layers including, sequentially, a cathode, an organic layered element, and an anode. The organic layered element typically includes several organic layers which include, in sequence, an electron transport layer (ETL), a light emissive layer (EL), and a hole transport layer (HTL). The entire structure is present on a substrate such as glass. When a voltage is applied to an OLED structure, the positive and negative charges from holes injected from the anode and electrons injected from the cathode radiatively recombine in the emissive layer, resulting in electroluminescence, as shown in FIG. 1. Light is emitted from the device through the substrate. As a result, OLED displays emit light, in contrast with conventional display technologies such as LCD displays which simply modulate transmitted or a reflected light.

Light incident on the organic element—glass interface or the glass—air interface, at angles larger than the critical angle, will be waveguided to the edges of the structure and will not be emitted from the device. Increasing light extraction is desired to achieve efficient conversion of electrical to optical power in OLED light-emitters. The critical angle beyond which incident light cannot cross the interface between two materials of differing refractive indices is given by Snell's Law:

Θ_{critical}=arcsin(n₂/n₁)

It is desired to provide optimal optical impedance matching between layers, to thereby maximum light extraction from an optical device such as an OLED. This invention combines refractive index (RI) matching materials with optical device technology, to provide unique structures having enhanced light extraction efficiency, among other benefits. The inventive method and structure notably improves light extraction, via the application of a RI-matched and optimized nanoporous thin film onto a transparent substrate. Such a tunable, low refractive index film on an outside surface of a substrate, such as glass, offers an optical impedance matching between the glass substrate and air, thereby enhancing light extraction. The low refractive index film exhibits excellent transparency from 190 to 1000 nm, and a refractive index which is low and tunable from 1.05 to 1.40. This refractive index range offers excellent optical impedance matching at the glass-air interface of a glass substrate. Optical devices incorporating such low refractive index materials benefit from improved light extraction, good gap fill and planarization performance, good thermal stability, and lower device cost.

### SUMMARY OF THE INVENTION

The invention provides a method of producing a nanoporous organosilicate film comprising

(a) preparing a composition comprising a silicon containing pre-polymer, a porogen, and a catalyst;

(b) coating a substrate which is substantially transparent to visible light with the composition to form a film,

(c) crosslinking the composition to produce a gelled film, and

(d) heating the gelled film at a temperature and for a duration effective to remove substantially all of said porogen to thereby form a cured nanoporous organosilicate film which is substantially transparent to visible light.

The invention further provides a lighting device comprising an organic light emitting diode which comprises, sequentially:

(a) a cathode layer;

(b) an organic layered element on the cathode layer, which organic layered element comprises, in sequence:
i) a hole transport layer;
ii) a light emissive layer; and
iii) an electron transport layer;

(c) an anode layer on the organic layered element;

(d) optionally, a high refractive index dielectric film on the anode layer; and

(e) a transparent article on the anode layer, or on the high refractive index dielectric film if present, which transparent article comprises a substantially transparent nanoporous organosilicate film on a substantially transparent substrate, and wherein the transparent article is present on the anode layer, or on the high refractive index dielectric film if present, such that the substantially transparent substrate is on a surface of the anode layer, or on a surface of the high refractive index dielectric film if present.

### BRIEF DESCRIPTION OF THE DRAWINGS

FIG. 1 shows a side schematic view of a conventional OLED device.

FIG. 2 shows a graphical view of comparing the fraction of light emitted from a lighting device, as a function of a critical angle at an interface between layers of the device.

FIG. 3A shows a side schematic view of an OLED device of the present invention, including a single low refractive index nanoporous film on a transparent substrate, and further including a high refractive index dielectric film.

FIG. 3B shows a side schematic view of an OLED device of the present invention, including multiple low refractive index nanoporous films on a transparent substrate, and further including a high refractive index dielectric film.

FIG. 3C shows a side schematic view of an OLED device of the present invention, including a single low refractive index nanoporous film on a transparent substrate, which low refractive index film has a reticulated outer surface.

FIG. 4A shows a side schematic view of light waves being emitted through an optical layer having non-reticulated surface.

FIG. 4B shows a side schematic view of light waves being emitted through an optical layer having a reticulated surface.

FIG. 4C. shows a top schematic view of an optical layer having a reticulated surface.

FIGS. 5A-5G show side schematic views of several substrate embodiments of the invention.

FIG. 6 shows a graphical representation of the dependence of refractive index and dielectric constant on the porosity of a film.

FIG. 7 shows a graphical representation of the infrared spectrum of a Methylsiloxane A film, at the post-bake and post-cure points, according to the Examples.

FIG. 8 shows a graphical representation of the refractive index and extinction coefficient values for a low refractive index Methylsiloxane A film, according to the Examples.

FIG. 9A shows a graphical representation of the refractive index of a Methylsiloxane B Film, according to the Examples.

FIG. 9B shows a graphical representation of the extinction coefficient for a Methylsiloxane B Film, according to the Examples.

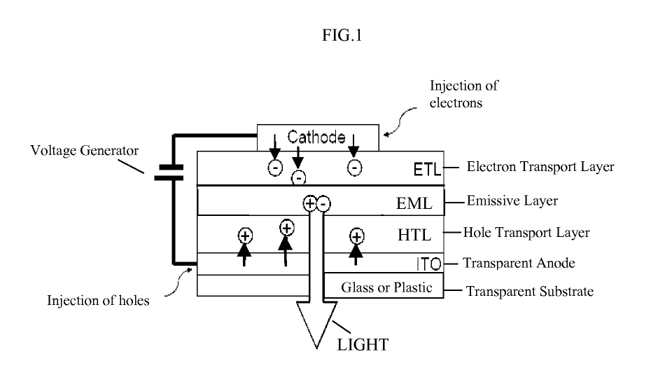

### DETAILED DESCRIPTION OF THE INVENTION

The invention relates to optical devices, including active and passive lighting devices, which comprise a substantially transparent nanoporous organosilicate film on a substantially transparent substrate, as formed by the method described below.

The inventive method first includes the step of preparing a composition comprising a silicon containing pre-polymer, a porogen, and a catalyst.

A useful silicon containing prepolymer comprises Formula I:

Rx-Si-Ly (Formula I)

wherein x is an integer ranging from 0 to about 2, and y is 4-x, an integer ranging from about 2 to about 4;

R is independently selected from the group consisting of alkyl, aryl, hydrogen, alkylene, arylene, and combinations thereof;

L is an electronegative moiety, independently selected from the group consisting of alkoxy, carboxyl, acetoxy, amino, amido, halide, isocyanato and combinations thereof.

As an example, if L is ethoxy, then the sol-gel reaction leading to formation of Si—O—Si bond can be described below:

SiOEt+H₂O==>SiOH+EtOH Hydrolysis

2SiOH==>Si—O—Si+H₂O Condensation

SiOH+SiOEt==>Si—O—Si+EtOH Condensation

Extensive Si—O—Si bonding will eventually yield a gelled network.

As an example, if L is acetoxy, then the sol-gel reaction will have a by-product of acetic acid. The reaction scheme is:

SiOAc+H₂O==>SiOH+AcOH Hydrolysis

2SiOH==>Si—O—Si+H₂O Condensation

SiOH+SiOAc==>Si—O—Si+HOAc Condensation

Acetic acid is a corrosive material and may pose damage to metal lines.

Examples of suitable silicon containing pre-polymers nonexclusively include alkoxysilanes such as tetraethoxysilane, tetrapropoxysilane, tetraisopropoxysilane, tetra(methoxyethoxy)silane, tetra(methoxyethoxyethoxy)silane, alkylalkoxysilanes such as methyltriethoxysilane silane, arylalkoxysilanes such as phenyltriethoxysilane, precursors such as triethoxysilane which yield SiH functionality to the film, and combinations thereof. Other useful silicon containing pre-polymers are enumerated in U.S. patent application publication US2005/0106376, which is incorporated herein by reference in its entirety. Useful silicon containing pre-polymers further include commercially available spin-on-glasses (SOG), for example, Honeywell Accuglas® 111, 211, 311, 214, 314, 512, 512B, 218, and the like. Upon curing, these materials form either methylsiloxane or methylsilsesquioxane polymer. As an example, Honeywell's Accuglas® 211 has 7.5% solid content after curing at 400° C. The cured material is a methylsiloxane comprising 58 mole % SiO₂ and 42 mole % CH₃SiO_{1.5}.

The composition further contains at least one porogen. A porogen may be a compound or oligomer or polymer, and is selected so that when it is removed, e.g., by the application of heat, a dielectric film is produced that has a nanometer scale porous structure. According to the present invention, it is preferred that the resulting nanoporous film comprises a plurality of pores, with an average pore diameter ranging from about 100 nanometers or less, preferably from about 1 to about 50 nanometers, and most preferably from about 2 to about 20 nanometers. The molecular weight distribution of the porogen can be monodisperse or polydisperse. In one embodiment, it is preferred that the porogen is a monodisperse compound that has a substantially homogeneous molecular weight and molecular dimension, and not a statistical distribution or range of molecular weights, and/or molecular dimensions, in a given sample. The avoidance of any significant variance in the molecular weight distribution allows for a substantially uniform distribution of pore diameters in a film formed by the inventive processes. There may be minimal variation in diameters of pores in a given film. However, if the film has a wide distribution of pore sizes, the likelihood is increased of forming one or more large pores, i.e., bubbles, which could interfere with device production.

An important feature of this invention is that the pore size and pore distribution of the resulting nanoporous films from this composition may be tuned such that the film exhibits a particular desired refractive index, as described below. It is important to optimize the organosiloxane polymer, to tune the pore structure (shape, size and distribution) and the volume fraction of the pores of the resulting films, in order to maximize the light extraction of formed OLED devices.

The porogen preferably has a suitable molecular weight and structure such that may be readily and selectively removed from the film without interfering with film formation. Broadly, a porogen should be removable from the newly formed film at temperatures below, e.g., about 450° C. In particular embodiments, depending on the desired post film formation fabrication process and materials, the porogen is selected to be readily removed at temperatures ranging from about 150° C. to about 450° C. during a time period ranging, e.g., from about 30 seconds to about 60 minutes. The removal of the porogen may be induced by heating the film at or above atmospheric pressure or under a vacuum, or by exposing the film to radiation, or both.

Porogens which meet the above characteristics include those compounds and polymers which have a boiling point, sublimation temperature, and/or decomposition temperature (at atmospheric pressure) range, for example, from about 150° C. to about 450° C. In addition, porogens suitable for use according to the invention include those having a molecular weight ranging, for example, from about 100 to about 200,000 amu, and more preferably in the range of from about 300 to about 3,000 amu. Furthermore, the scale of the pores produced by porogen removal is proportional to the effective steric diameters of the selected porogen component.

Porogens suitable for use in the processes and compositions of the invention include polymers, preferably those which contain one or more reactive groups, such as hydroxyl or amino. Within these general parameters, a suitable polymer porogen for use in the compositions and methods of the invention is, e.g., a polyalkylene oxide, a monoether of a polyalkylene oxide such as polyethylene oxide monomethyl ether, an aliphatic polyester, an acrylic polymer, an acetal polymer, a poly(caprolactone), a poly(valeractone), a poly(methyl methacrylate), a poly(vinylbutyral) and/or combinations thereof. When the porogen is a polyalkylene oxide monoether, one particular embodiment is a C₁ to about C₆ alkyl chain between oxygen atoms and a C₁ to about C₆ alkyl ether moiety, and wherein the alkyl chain is substituted or unsubstituted, e.g., polyethylene glycol monomethyl ether, polyethylene glycol dimethyl ether, or polypropylene glycol monomethyl ether.

Other useful porogens, disclosed in U.S. patent application publication 2005/0123735 which is incorporated herein by reference in its entirety, are porogens that do not bond to the silicon containing pre-polymer, and include a poly(alkylene)diether, a poly(arylene)diether, poly(cyclic glycol)diether, Crown ethers, polycaprolactone, fully end-capped polyalkylene oxides, fully end-capped polyarylene oxides, polynorbene, and combinations thereof. Certain porogens which do not bond to the silicon containing pre-polymer include poly(ethylene glycol)dimethyl ethers, poly(ethylene glycol) bis(carboxymethyl)ethers, poly(ethylene glycol) dibenzoates, poly(ethylene glycol) diglycidyl ethers, a poly(propylene glycol)dibenzoates, poly(propylene glycol)diglycidyl ethers, poly(propylene glycol)dimethyl ether, 15-Crown 5, 18-Crown-6, dibenzo-18-Crown-6, dicyclohexyl-18-Crown-6, dibenzo-15-Crown-5 and combinations thereof.

Without meaning to be bound by any theory or hypothesis as to how the invention might operate, it is believed that porogens that are “readily removed from the film” undergo one or a combination of the following events: (1) physical evaporation of the porogen during the heating step, (2) degradation of the porogen into more volatile molecular fragments, (3) breaking of the bond(s) between the porogen and the Si containing component, and subsequent evaporation of the porogen from the film, or any combination of modes 1-3. The porogen is heated until a substantial proportion of the porogen is removed, e.g., at least about 20% by weight, or more, of the porogen is removed. More particularly, in certain embodiments, depending upon the selected porogen and film materials, at least about 50% by weight, or more, of the porogen is removed. Thus, by “substantially” is meant, simply by way of example, removing from about 20% to about 85%, or more, of the original porogen from the applied film.

The porogen is preferably present in the overall composition in an amount ranging from about 1 to about 50 weight percent, or more. More preferably the porogen is present in the composition, in an amount ranging from about 2 to about 20 weight percent.

The composition further contains at least one catalyst for condensation reaction. The catalyst serves to aid in the polymerization/gelation (or “crosslinking”) of the film during an initial heating step, as described below. Suitable catalysts nonexclusively include onium compounds such as an ammonium compound, a phosphonium compound, a sodium ion, an alkali metal ion, an alkaline earth metal ion, or combinations thereof. Specific examples of suitable catalysts nonexclusively include tetraorganoammonium compounds including tetramethylammonium acetate, tetramethylammonium hydroxide, tetrabutylammonium acetate, tetramethylammonium nitrate, and combinations thereof. Examples of Alkali metal ions nonexclusively include potassium ions, sodium ions, and lithium ions. Examples of alkaline earth metal ions nonexclusively include magnesium and calcium. Other useful catalysts are enumerated in U.S. patent application publication US2005/0106376. The catalyst is preferably present in the overall composition in an amount of from about 1 ppm by weight to about 1000 ppm, preferably present in the overall composition in an amount of from about 6 ppm to about 200 ppm.

In forming the composition, the silicon containing pre-polymer, the porogen, and the catalyst may be combined using any suitable conventional methods such as mixing, blending, or the like. The composition is then applied onto a substrate, using any suitable conventional method such as spraying, rolling, dipping, coating such as spin-on coating, spray-on coating, flow coating, casting, chemical vapor deposition, and the like. Spin-on coating is preferred.

The substrate preferably comprises a light emitting or light transmitting layer. An important feature of the invention is that the substrate is substantially transparent to visible light. The substrate is preferably at least 98% transparent to visible light. In a preferred embodiment, the substrate is at least 98% transparent visible light and ultraviolet light in the 200 nm to 800 nm wavelength range. Suitable transparent substrates nonexclusively include glass, sapphire, or organic polymers such as polydicyclo-pentadiene, polycarbonates, or acrylics. The substrate may comprise a single material layer or a plurality of material layers. Several multi-layered substrate configurations are described in detail below.

The composition on the substrate is next crosslinked to produce a gelled film. Those skilled in the art will appreciate that specific temperature ranges suitable for crosslinking and porogen removal from the nanoporous dielectric films will depend on the selected materials, substrate, and desired nanoscale pore structure, as is readily determined by routine manipulation of these parameters. Generally, the coated substrate is subjected to a treatment such as heating to effect crosslinking of the composition on the substrate to produce a gelled film. The crosslinking may be conducted by heating the film at a temperature ranging from about 100° C. to about 250° C., for from about 30 seconds to about 10 minutes.

The gelled film is then heated at a temperature and for a duration effective to remove substantially all of the porogen, and to thereby form a cured film. Those skilled in the art will appreciate that specific temperature ranges for curing such a gelled film. In one embodiment, the gelled film is cured by heating at a temperature ranging from about 150° C. to about 450° C., for from about 30 seconds to about 1 hour.

The resulting cured nanoporous organosilicate film is substantially transparent to visible light. Preferably, the cured film is at least about 98% transparent to visible light. Further, the cured film is preferably at least about 98% transparent to visible light and ultraviolet light in the 200 nm to 800 nm wavelength range. In a preferred embodiment, both the cured film and the substrate are at least about 98% transparent to visible light. In a further preferred embodiment, both the cured film and the substrate are at least about 98% transparent visible light and ultraviolet light in the 200 nm to 800 nm wavelength range.

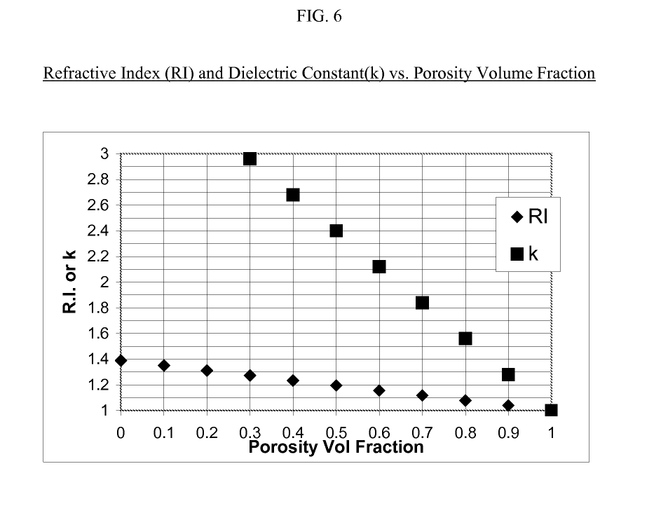

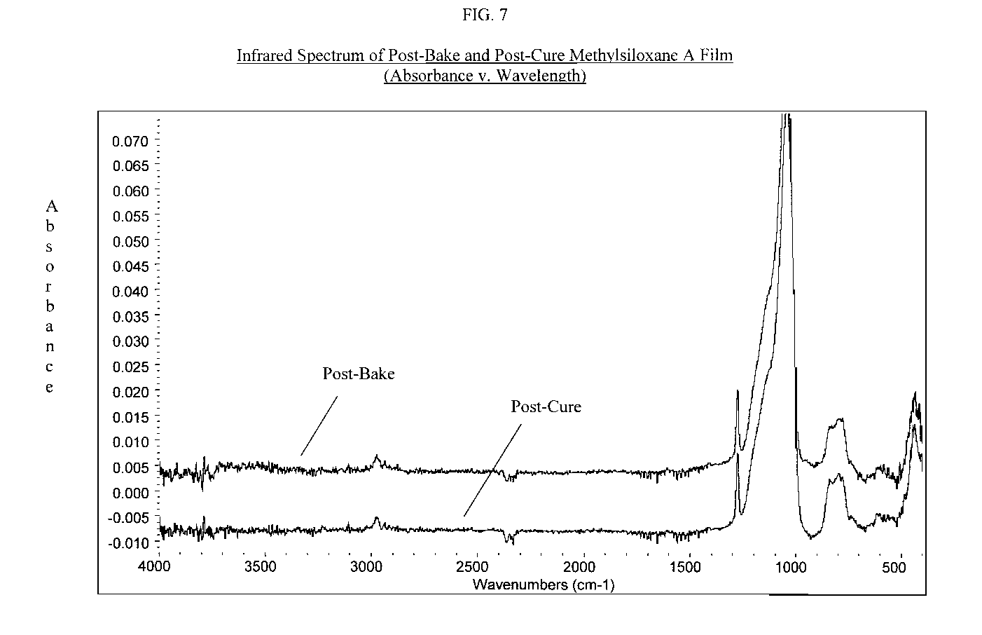

The resulting cured film preferably has a refractive index of from about 1.05 to about 1.4, more preferably from about 1.15 to about 1.3, and most preferably from about 1.2 to about 1.3. The resulting cured film preferably has a dielectric constant of from about 1.3 to about 4.0, more preferably from about 1.9 to about 2.6, and most preferably from about 1.5 to about 3.5. The dielectric constant and refractive index values depend on the degree of porosity of the film. FIG. 6 shows the relationship of both refractive index (RI) and dielectric constant (k) as they relate to the volume fraction of pores in a film. As shown in FIG. 6, it is typical that as a film's volume fraction of pores (porosity) increases, dielectric constant decreases drastically and refractive index decreases gradually.

A material of low refractive index (RI) is defined herein as a material having a RI value ranging from about 1.05 to about 1.4. Preferred low refractive index ranges for this invention are listed above. Preferably, low refractive index films of the invention are formed such that their refractive index may be controlled to within this range by varying the porosity of the coating. The tunable nature of such a film depends on the size and volume fraction of the pores, as well as the composition and chemical structure of the coating composition. Optimizing the coating material contributes to a particularly desired refractive index, and thus to maximized light extraction properties of a lighting device. The low refractive index nanoporous films formed according to this invention exhibit a transparency which is excellent (≧98% transparent) at wavelengths of from about 190 to 1000 nm, and they have excellent thermal stability (<1% weight loss) at temperatures above 450° C. They also exhibit excellent gap-fill properties and planarization performance. Extinction coefficient is defined herein as the fraction of light lost to scattering and absorbtion per unit distance in a participating medium. The materials of this invention have a low extinction coefficient, that is, light passes easily through these materials.

A material of high refractive index (RI) is defined herein as a material having a RI value ranging from about 1.5 to about 1.8, or more. In certain embodiments of the invention where high refractive index films are formed, organosiloxane polymers doped with a high refractive index oxide may be used in forming a film that has a tunable high refractive index within this range. The incorporation of metal oxides or other metals such as Ti, Zr, and Al into the composition, prior to forming the film, will increase the refractive index of a resulting film. Examples of refractive indexes of various metal oxides include:
Titanium dioxide (TiO₂)—2.5
Zirconium (IV) oxide (ZrO₂)—2.2
Aluminum oxide (Al2O₃)—1.77
Tin oxide (SnO₂)—2.09
Hafnium oxide (HfO₂)—1.98
Barium oxide (BaO)—1.98
Tantalum Pentaoxide (Ta₂O₅)—2.15

A high refractive index may be achieved as a result of the choice of polymer for the coating composition, the choice of doping oxide, and their volume ratio. By using phenyl-containing silicates, the refractive index may also be increased.

The above method results in the formation of a transparent article which comprises a low refractive index, cured nanoporous organosilicate film on a substantially transparent substrate. Such transparent articles may be used in the formation of a variety of optical devices, such as light emitting diodes (LED), organic light emitting diode (OLED) devices, polarizers, and photonic bandgap devices. One specific example is a cathode ray tube faceplate.

The intensity of light which passes through a substrate of an optical device can be defined in terms of illuminance, otherwise known as luminous flux. The term “lux” is the SI unit for illuminance and luminous emittance, which is used in photometry as a measure of the intensity of light, with wavelengths weighted according to the luminosity function, a standardized model of human brightness perception. A lux is defined herein as one lumen per square meter, where one lumen equals 1/683 watts, emitted at a 555 nm wavelength. As an example, outdoor LEDs typically have an illuminance output of 600-200 Lux, indoor LEDs typically have an illuminance output of 20-120 Lux, and film sets typically have an illuminance output of about 3000 Lux. For purposes of this invention, a variety of lighting devices having a variety of Lux values are envisioned. For example, the inventive devices may cover an illuminance output range of from about 3 Lux to about 6000 Lux. The term “illuminance output” refers to the transmission of light which is exiting the device.

Optical devices which include the transparent articles of this invention exhibit improved light extraction and illuminance due to the present tunable, low refractive index nanoporous films. That is, devices which incorporate these tunable, low refractive index nanoporous films on a transparent substrate exhibit an increase in the luminous flux passing through the substrate by about 10% or more, as compared to an equivalent device which does not incorporate the present low refractive index nanoporous films. Preferably the inventive materials increase the luminous flux of such devices by about 30% or more, more preferably by about 50% or more, and most preferably by about 75% or more. For example, where a conventional optical device has a Lux value of 100, an identical device which incorporates the present films would have a Lux value of at least 110, preferably at least 130 or 150, and most preferably at least 175.

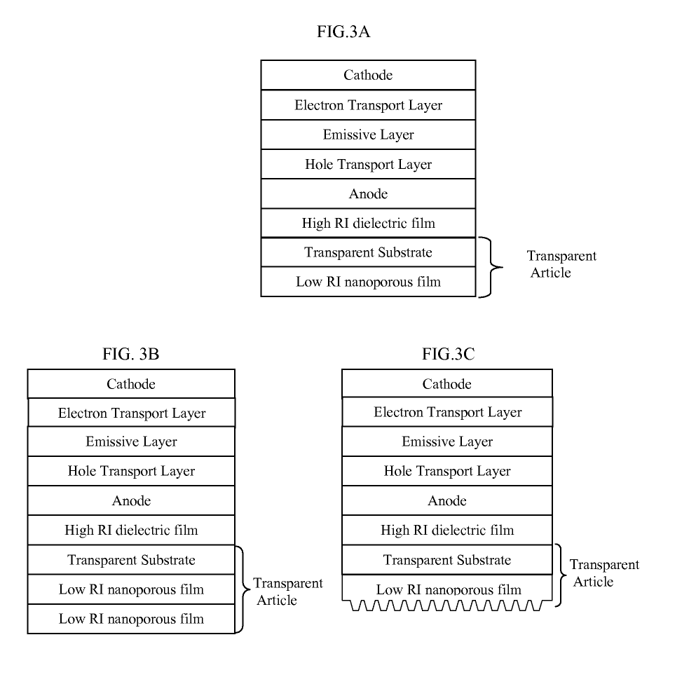

In certain embodiments of this invention, as shown in FIG. 3A-3C, an OLED device is formed which comprises a cured nanoporous organosilicate film on a substantially transparent substrate, which cured film on the substrate is formed according to the above method. FIGS. 3A-3C show such OLED devices of this invention as having a structure which includes a cathode layer such as a reflective metal cathode, an organic layered element, and an anode layer such as a transparent conductive oxide (TCO) anode, which may include a material such as indium tin oxide (ITO). The organic layered element comprises an arrangement of several organic material layers, including an electron transport layer (ETL), an emissive layer (EL), and a hole transport layer (HTL). Such organic material layers comprise organic compounds which are well known in the OLED art. Examples of suitable organic materials for these layers nonexclusively include copper phthalocyanine (CuPc), N,N-di(naphthalene-1-yl)-N,N′-diphenyl-benzidine (NPD), and tris(8-hydroxyquinoline) aluminium (Alq3). Conventional OLED devices further comprises a light emitting substrate, such as glass, on the anode layer. The aforementioned components of an OLED are well known in the art. However, this invention provides OLED structures which differ from what is conventionally known. A key feature of these inventive structures includes the incorporation of the RI-tunable films described below, which serve as impedance matching layers. These films serve to enhance light extraction of devices which include such films, as compared to conventional devices.

As stated above, a disadvantage of known light emitting devices relates to the waveguiding of light to the edges of the device. This is a consequence of the difference in refractive index between a light emitting substrate material and air, which causes light rays reaching the substrate-air interface beyond a critical angle to be reflected back into the material layer. This critical angle θ_{critical} is given by the Fresnel Equations, or more simply by Snell's Law:

θ_{critical}=arcsin(n₂/n₁) Eq. (1)

Since n₂, the refractive index of air, is one,

θ_{critical}=arcsin(1/n₁) Eq. (2)

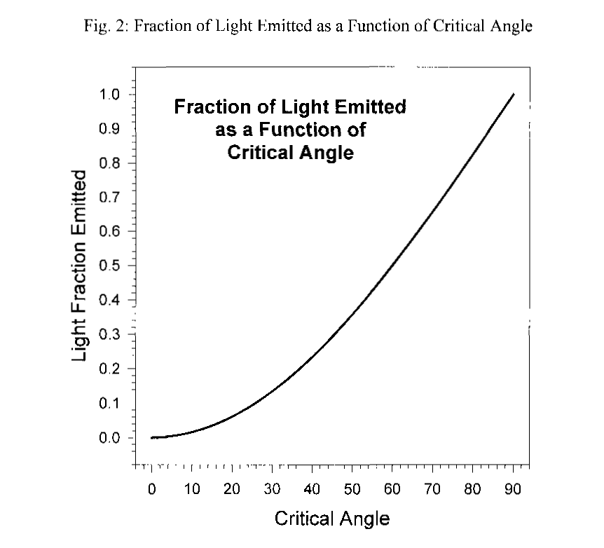

which shows that low refractive index materials allow extraction of a greater fraction of light. FIG. 2 shows a graphic representation of the fraction of light emitted, as a function of the critical angle

In cases where the refractive index of a light-emitting substrate is high, an optical impedance matching layer is desirable, for extracting a greater fraction of light. Such an impedance matching layer, to be placed at the interface where the light-emitting substrate meets the air, should have a refractive index intermediate between the light emitting substrate material and air. The inventive RI-tunable films are capable of optical impedance matching at both the outside (substrate-air) and the inside (anode-substrate) interfaces of the OLED's substrate.

Accordingly, the inventive OLED structures may first differ from conventional OLEDs by the inclusion of an impedance matching layer in the form of a high refractive index dielectric film (RI of about 1.5-1.8) on the anode layer. Such is shown in FIGS. 3A-3C. A high refractive index dielectric film is optionally, but preferably, present between the anode layer and a substrate as described below, to thereby bridge the gap in refractive index (RI) at the substrate-anode interface, further enhancing light extraction where the RI of a transparent conductive oxide (TCO) anode is about 1.8-1.9 and the RI of a glass substrate is about 1.58. Such high refractive index dielectric films are described above, and may comprise doped organosiloxane polymers and the like.

A key feature of the inventive OLED structures is that they comprise a transparent article as described above. The transparent article comprises a substantially transparent nanoporous organosilicate film on a substantially transparent substrate, which is formed according to the method described above. The substantially transparent nanoporous organosilicate film preferably comprises a low refractive index nanoporous film as described above. The transparent article is present on the anode layer, or on the high refractive index dielectric film if present, such that the substrate is present on a surface of the anode layer, or on a surface of the high refractive index film if present. Accordingly, the low refractive index nanoporous film is present on an outer surface of the substrate, which outer surface is opposite the anode layer or high refractive index film, if present. Such is shown for example in FIGS. 3A-3C. In a preferred embodiment, both the substrate and the cured film are at least 98% transparent to visible light. As stated above, it is preferred that the substantially transparent nanoporous organosilicate film of this transparent article comprises a low refractive index nanoporous film, having a refractive index of from about 1.05 to about 1.4. The low refractive index nanoporous film serves as an impedance matching layer which bridges the gap in refractive index (RI) at the substrate-air interface, where the RI of air is about 1.00 and the RI of a glass substrate is about 1.58. As stated above, the low refractive index nanoporous films of this invention exhibit a transparency which is excellent from 190 to 1000 nm, and a thermal stability above 450° C.

In certain embodiments, multiple low refractive index films may be present on the outside surface of the transparent substrate. FIG. 3A shows an embodiment where one low refractive index nanoporous film is present on the substrate's outer surface. FIG. 3B shows an embodiment where multiple low refractive index nanoporous films are present.

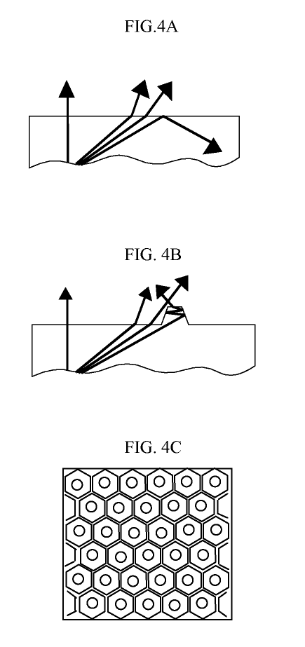

In certain embodiments, increased light extraction may be achieved by providing a textured or reticulated surface of the a low refractive index nanoporous film on an outer surface of the OLED structure. FIG. 3C shows a schematic view of an OLED structure having a low refractive index film with a reticulated surface. FIGS. 4A and 4B show the light extraction properties of a non-reticulated surface versus a reticulated surface. FIG. 4B shows that such surface features extract a greater fraction of light from an emitting layer, such that light rays which would have been waveguided to the edge are now reflected towards the surface. A top view of a reticulated surface having truncated hexagonal base prisms etched therein is shown in FIG. 4C.

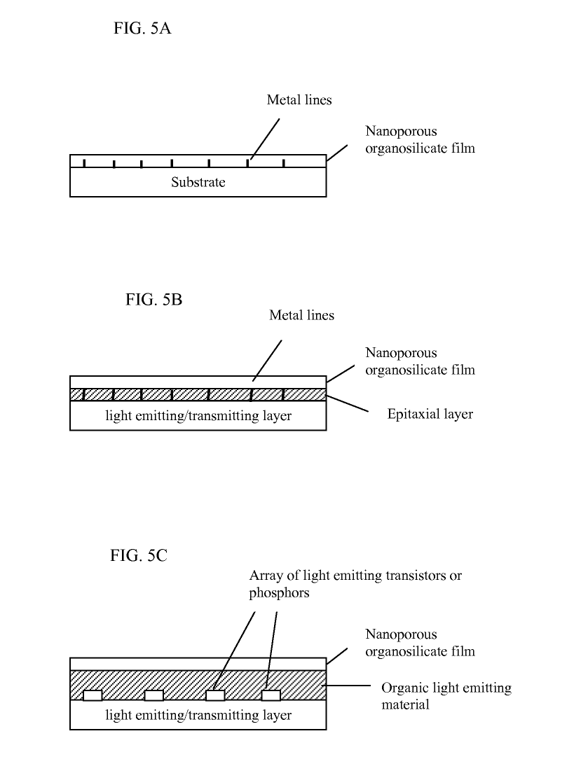

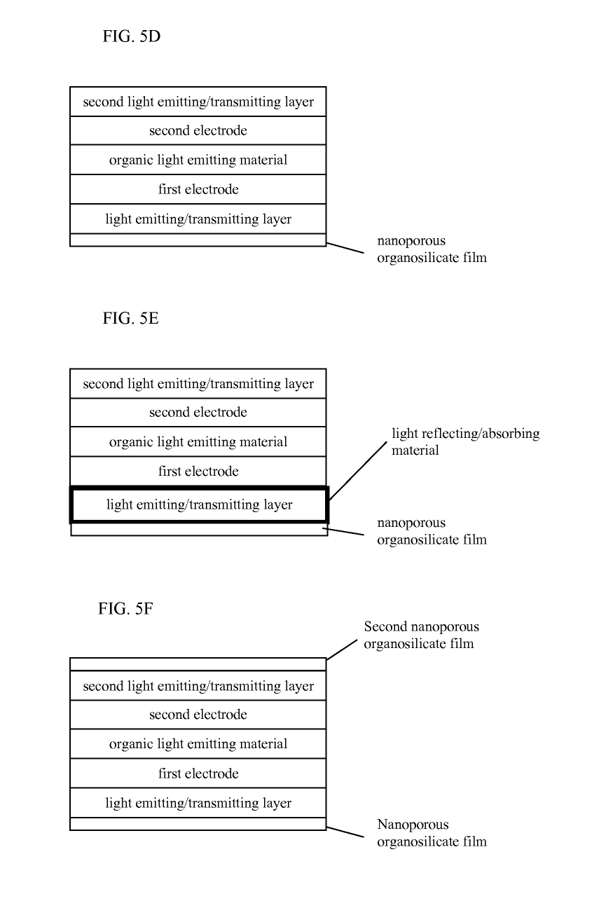

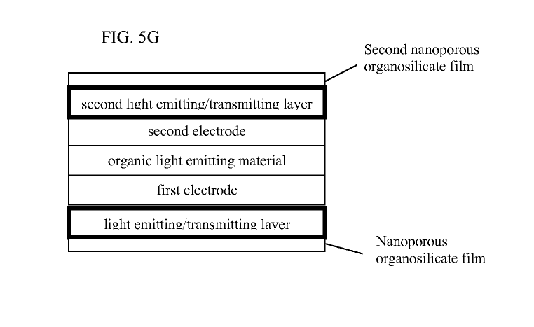

In further embodiments of this invention, a variety of substrate structures may be used in forming the inventive transparent articles. As stated above, the inventive substrate is substantially transparent to visible light, and preferably comprises a light emitting or light transmitting layer. In several embodiments of this invention, substrate may comprise additional features and/or multiple layers. First, in certain embodiments, on the surface of the substrate there may be an optional array of raised lines, such as metal, oxide, nitride or oxynitride lines which are formed by well known lithographic techniques. Suitable materials for the lines include silica, silicon nitride, titanium nitride, tantalum nitride, aluminum, aluminum alloys, copper, copper alloys, tantalum, tungsten and silicon oxynitride. Useful metallic targets for making these lines are taught in commonly assigned U.S. Pat. Nos. 5,780,755; 6,238,494; 6,331,233B1; and 6,348,139B1 and are commercially available from Honeywell International Inc. These lines form the conductors or insulators of an integrated circuit. Such are typically closely separated from one another, wherein the spacing between the lines preferably ranges from about 0.1 micrometers to about 2.0 micrometers apart, more preferably from about 0.1 micrometers to about 0.8 micrometers apart, and most preferably from about 0.35 micrometers to about 0.75 micrometers apart. In certain embodiments the array of lines comprises an array of substantially parallel lines. In certain embodiments, the nanoporous organosilicate film of the invention may be present on the substrate such that it covers and/or lies between the optional lines on the substrate, if present. Such an embodiment is shown in FIG. 5A.

In certain embodiments, the substrate may have a multi-layered structure. In one embodiment, shown in FIG. 5B, the inventive structure includes a substrate which comprises a light emitting or light transmitting layer as described above, and an epitaxial layer on the light emitting or light transmitting layer, which epitaxial layer comprises a doping amount of n-type or p-type doping material in at least an uppermost portion of the epitaxial layer. Suitable materials for the epitaxial layer nonexclusively include aluminum oxide, silicon carbide, gallium nitride, indium gallium phosphide, indium gallium arsenide, indium tin oxide or combinations thereof. Examples of suitable materials for the doping material nonexclusively include group III and group V elements. In this embodiment, the substrate further comprises an array of metal lines as described above, through the epitaxial layer, and wherein the nanoporous film is positioned on the epitaxial layer and on the array of metal lines. In a further embodiment, the light emitting or light transmitting layer comprises sapphire.

In a further embodiment, shown in FIG. 5C, the inventive structure includes a substrate which comprises a light emitting or light transmitting layer as described above, an array of light emitting transistors or phosphors on the light emitting or light transmitting layer; and an organic light emitting material on and between the array of light emitting transistors or phosphors. Phosphors are well known in the art as a light source in the cathode ray tube industry. Light emitting transistors are a recent development in the art. Traditional transistors turn on-turn off when subject to an applied voltage. Light emitting transistors create light under the stimulus of a traditional transistor. Suitable materials for the organic light emitting material nonexclusively include Alq₃ and other similar conventionally known materials. In this embodiment, the nanoporous film is positioned on the organic light emitting material.

In another embodiment, shown in FIG. 5D, the inventive structure includes a substrate which comprises sequentially: a first light emitting or light transmitting layer; a first electrode on the first light emitting or light transmitting layer; an organic light emitting material on the first electrode; a second electrode on the organic light emitting material; and a second light emitting or light transmitting layer on the second electrode. Suitable materials for the first and second light emitting or light transmitting layers are described in detail above. The first and second light emitting or light transmitting layers may be the same or different. Electrodes are well known in the art, and typically include a metallic or conductive cathode, paired with a transparent anode. Such electrodes may include patterned conductors of materials such as aluminum, silver, indium tin oxide, copper, nickel, tungsten, indium zinc oxide. Furthermore, in this embodiment, the nanoporous film is positioned on the first light emitting or light transmitting layer. This embodiment may further comprise a light reflecting or light absorbing material positioned around a perimeter of the first light emitting or light transmitting layer between the first light emitting or light transmitting layer and the nanoporous dielectric, as shown in FIG. 5E. Suitable light reflecting materials nonexclusively include mirrors and highly planar or polished metals, such as planar or polished aluminum. Suitable light absorbing materials nonexclusively include rare earth oxides, carbon black, and metals such as rough metals. Alternatively, this embodiment may further comprise a second nanoporous dielectric positioned on the second light emitting or light transmitting layer, as shown in FIG. 5F. Further, this alternative embodiment may also comprise a light reflecting or light absorbing material positioned around a perimeter of the first light emitting or light transmitting layer between the first light emitting or light transmitting layer and the nanoporous dielectric; and second light reflecting or light absorbing material positioned around a perimeter of the second light emitting or light transmitting layer between the second light emitting or light transmitting layer and the second nanoporous dielectric, as shown in FIG. 5G.

A variety of other arrangements may be configured using the above layers.

The following non-limiting examples serve to illustrate the invention. It will be appreciated that variations in proportions and alternatives in elements of the components of the invention will be apparent to those skilled in the art and are within the scope of the present invention.

### EXAMPLE 1

### Comparative

3 g of Methylsiloxane Solution A (Honeywell Accuglas° 211) was spun onto a 6″ silicon wafer at a spin speed of 3000 rpm. The film was formed and baked at temperatures of 125° C./200° C./300° C. for one minute each and then cured at 400° C. in nitrogen for 30 minutes. A nonporous film was formed with dielectric constant of 3.8 and refractive index of 1.39. The infrared spectrum of the post-bake and post-cure films are depicted as the top and bottom curves, respectively, in FIG. 7, showing the presence of SiC and CH bonds.

### EXAMPLE 2

22.5 g of Methylsiloxane Solution A (Honeywell Accuglas® 211) was mixed with 2.35 g polyethylene oxide monomethyl ether (PEO) (Mw=500) as a porogen. After mixing, 46.65 g of propylene glycol methyl ether acetate (PGMEA) solvent and 0.72 g of 1% Tetramethylammonium acetate in acetic acid (TMAA) catalyst were added. The resulting mixture was filtered through 0.2 um Teflon filter. The solution was spin-coated onto 4″ silicon wafer using SVG coater and baked at temperatures of 125° C./200° C./300° C. for one minute each. Post bake refractive indexes were listed below.

| Spin Speed | R.I. | Thickness |
|---|---|---|
| 1000 rpm | 1.216 | 1396 A |
| 2000 rpm | 1.210 | 970 A |
| 4000 rpm | 1.212 | 680 A |

### EXAMPLE 3

18.0 g of Methylsiloxane Solution A (Honeywell Accuglas® 211) was mixed with 2.12 g polyethylene oxide monomethyl ether (PEO) (Mw=500) as a porogen. After mixing, 6.29 g of the mixture was added to 8.80 g of propylene glycol methyl ether acetate (PGMEA) solvent and 0.15 g of 1% Tetramethylammonium acetate in acetic acid (TMAA) catalyst. The resulting mixture was filtered through 0.2 um Teflon filter, and spin-coated at 2100 rpm onto 4″ silicon wafer and baked at temperatures of 125° C./200° C./300° C. for one minute each. The post-bake refractive index was 1.197 and post-bake thickness was 1306A.

### EXAMPLE 4

843 g of Methylsiloxane Solution A (Honeywell Accuglas® 211), 116 g of polyethylene oxide monomethyl ether (PEO) (Mw=500) as a porogen, 1200 g of propylene glycol methyl ether acetate (PGMEA) solvent and 21.8 g of 1% Tetramethylammonium acetate in acetic acid (TMAA) catalyst were mixed together. The mixture was filtered through 0.04 um Teflon filter and spin-coated onto 6″ silicon wafer at different spin speeds. The coated wafers were baked at temperatures of 125° C./200° C./300° C. for one minute each and then cured at 400° C. in nitrogen for 30 minutes.

| | Post Bake | Post Bake | | Post Cure |
|---|---|---|---|---|
| Spin | Thickness, | Refractive | Post Cure | Refractive |
| Speed | A | Index | Thickness | Index |
| 1000 rpm | 2030 | 1.178 | 1945 | 1.174 |
| 1100 rpm | 1925 | 1.178 | 1820 | 1.175 |
| 1700 rpm | 1580 | 1.180 | 1510 | 1.172 |
| 2150 rpm | 1410 | 1.177 | 1355 | 1.173 |
| 2800 rpm | 1245 | 1.175 | 1198 | 1.171 |

The mixture was also coated onto a glass substrate with smooth appearance, and good adhesion using an ASTM D3359-95 Test Method B Cross-cut Tape Test.

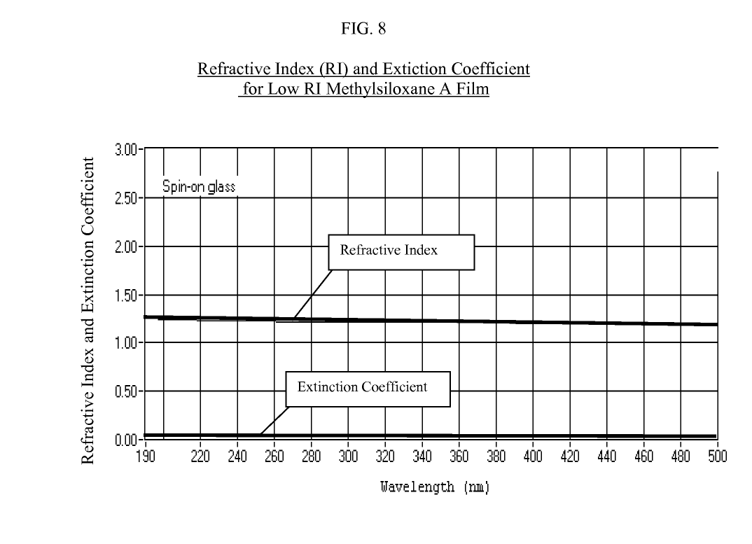

FIG. 8 shows the refractive index and extinction coefficient for the post-cure films, which are plotted as a function of wavelength from 190 nm to 500 nm. It can be seen that the refractive index is around 1.19 (top curve) and the extinction coefficient is less than 0.005 (bottom curve), indicating virtually no light absorption and excellent transparency.

### EXAMPLE 5

### Comparative

Methylsiloxane Solution B was prepared by combing 10 g tetraacetoxysilane, 10 g methyltriacetoxysilane, and 17 g propylene glycol methyl ether acetate (PGMEA) solvent in a glass flask. The mixture was heated under nitrogen blanket to 80° C. and 1.5 gm of water was added. A film was spin coated onto silicon wafer, baked at temperatures of 125° C./200° C./300° C. for one minute each, and then cured at 400° C. in nitrogen for 30 minutes. A non-porous film with a refractive index of 1.41 was obtained.

### EXAMPLE 6

38.5 g of Methylsiloxane Solution B of Example 5 was added to 4.26 g polyethylene oxide monomethyl ether (PEO) (Mw=500) as a porogen and 0.043 g 1% tetramethylammonium acetate (TMAA) in acetic acid were added. Methylsiloxane Solution B was spun onto a 6″ silicon wafer at a spin speed of 2000 rpm. The resulting film was baked at temperatures of 125° C./200° C./300° C. for one minute each and then cured at 400° C. in nitrogen for 30 minutes. A porous film was obtained with dielectric constant of 2.2 and refractive index of 1.24. An infrared spectrum of the post-cure film shows the presence of Si—C bond at 1277 cm⁻¹ and CH bond at 2978 cm⁻¹.

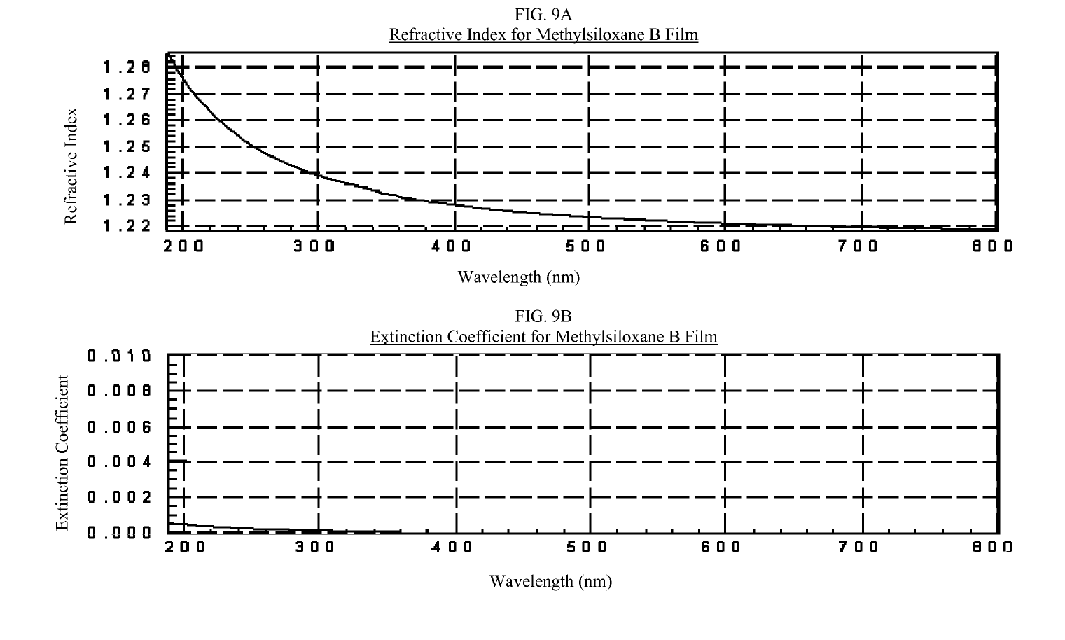

FIGS. 9A and 9B show the plots of refractive index and extinction coefficient as a function of wavelength from 190 nm to 800 nm. The extinction coefficient is less than 0.005 (FIG. 9B) for the entire wavelength range.

### EXAMPLE 7

A composition was prepared having 25.3 wt % Methylsiloxane Solution B of Example 5, 2.7 wt % polyethylene oxide monomethyl ether (PEO) (Mw=500) as a porogen, 70.8 wt % propylene glycol methyl ether acetate (PGMEA) solvent, and 1.2 wt % of 4% tetramethylammonium acetate in acetic acid (TMAA) catalyst. The composition was filtered through 0.04 um Teflon filter, and spin-coated onto 4-inch silicon wafers. The coated wafers were baked at temperatures of 125° C./200° C./300° C. for one minute each and then cured at 400° C. in nitrogen for 30 minutes.

| | Post Bake | Post Bake | | Post Cure |
|---|---|---|---|---|
| Spin | Thickness, | Refractive | Post Cure | Refractive |
| Speed | A | Index | Thickness | Index |
| 1550 rpm | 1865 | 1.145 | 1806 | 1.142 |
| 3500 rpm | 1240 | 1.145 | 1200 | 1.142 |
| 4490 rpm | 1100 | 1.145 | 1065 | 1.144 |

The composition was coated also onto a glass substrate with smooth appearance, and good adhesion using an ASTM D3359-95 Test Method B Cross-cut Tape Test.

The above Examples show that the refractive index of the inventive films, formed on a substrate, exhibited a lower refractive index where a porogen was used in the original composition (Examples 2, 3, 4, 6, and 7), as compared to films formed from compositions without a porogen (Examples 1 and 5).

While the present invention has been particularly shown and described with reference to preferred embodiments, it will be readily appreciated by those of ordinary skill in the art that various changes and modifications may be made without departing from the spirit and scope of the invention. It is intended that the claims be interpreted to cover the disclosed embodiment, those alternatives which have been discussed above and all equivalents thereto.

What is claimed is:

1. A method of producing a nanoporous organosilicate film comprising
(a) preparing a composition comprising a silicon containing pre-polymer, a porogen, and a catalyst;
(b) coating a substrate which is substantially transparent to visible light with the composition to form a film,
(c) crosslinking the composition to produce a gelled film, and
(d) heating the gelled film at a temperature and for a duration effective to remove substantially all of said porogen to thereby form a cured nanoporous organosilicate film which is substantially transparent to visible light.

2. The method of claim 1 wherein both the substrate and the nanoporous organosilicate film are at least 98% transparent to visible light.

3. The method of claim 1 wherein both substrate and the nanoporous organosilicate film are at least 98% transparent to visible light and ultraviolet light in the 200 nm to 800 nm wavelength range.

4. The method of claim 1 wherein the catalyst comprises an ammonium compound, a phosphonium compound, a sodium ion, an alkali metal ion, an alkaline earth metal ion, or combinations thereof.

5. The method of claim 1 wherein the composition comprises a silicon containing prepolymer of Formula I:
Rx-Si-Ly (Formula I)
wherein x is an integer ranging from 0 to about 2, and y is 4-x, an integer ranging from about 2 to about 4;
R is independently selected from the group consisting of alkyl, aryl, hydrogen, alkylene, arylene, and combinations thereof;
L is an electronegative moiety, independently selected from the group consisting of alkoxy, carboxyl, acetoxy, amino, amido, halide, isocyanato and combinations thereof.

6. The method of claim 1 wherein the porogen comprises a polyalkylene oxide, a monoether of a polyalkylene oxide, a diether of a polyalkylene oxide, bisether of a polyalkylene oxide, an aliphatic polyester, an acrylic polymer, an acetal polymer, a poly(caprolatactone), a poly(valeractone), a poly(methyl methacrylate), a poly(vinylbutyral) and combinations thereof.

7. The method of claim 1 wherein the crosslinking of step (c) is conducted by heating the film at a temperature ranging from about 100° C. to about 250° C., for from about 30 seconds to about 10 minutes.

8. The method of claim 1 wherein step (d) is conducted by heating the gelled film at a temperature ranging from about 150° C. to about 450° C., for from about 30 seconds to about 1 hour.

9. The method of claim 1 wherein the nanoporous organosilicate film has a refractive index of from about 1.05 to about 1.40, and a dielectric constant of from about 1.3 to about 4.0.

10. The method of claim 1 wherein the nanoporous organosilicate film has pores which have an average pore diameter of about 100 nanometers or less.

11. A transparent article comprising a substantially transparent nanoporous organosilicate film on a substantially transparent substrate, formed according to claim 1.

12. The transparent article of claim 11 wherein both the substrate and the nanoporous organosilicate film are at least 98% transparent to visible light.

13. The transparent article of claim 11 wherein both the substrate and the nanoporous organosilicate film are at least 98% transparent to visible light and ultraviolet light in the 200 nm to 800 nm wavelength range.

14. The transparent article of claim 11 wherein the substrate comprises glass or an organic polymer.

15. The transparent article of claim 11 wherein the nanoporous organosilicate film has a refractive index of from about 1.05 to about 1.40, and a dielectric constant of from about 1.3 to about 4.0.

16. The transparent article of claim 11 wherein the nanoporous organosilicate film has pores which have an average pore diameter of about 100 nanometers or less.

17. A lighting device comprising the transparent article of claim 11.

18. The lighting device of claim 17, which comprises a light polarizer device, a light emitting diode, an organic light emitting diode, or a photonic bandgap device.

19. A lighting device of claim 18 comprising an organic light emitting diode which comprises, sequentially:
(a) a cathode layer;
(b) an organic layered element on the cathode layer, which organic layered element comprises, in sequence:
i) a hole transport layer;
ii) a light emissive layer; and
iii) an electron transport layer;
(c) an anode layer on the organic layered element;
(d) optionally, a high refractive index dielectric film on the anode layer; and
(e) a transparent article on the anode layer, or on the high refractive index dielectric film if present, which transparent article comprises a substantially transparent nanoporous organosilicate film on a substantially transparent substrate, and wherein the transparent article is present on the anode layer, or on the high refractive index dielectric film if present, such that the substantially transparent substrate is on a surface of the anode layer, or on a surface of the high refractive index dielectric film if present.

20. The lighting device of claim 19 wherein both the substrate and the nanoporous organosilicate film are at least 98% transparent to visible light.

21. The lighting device of claim 19 wherein the high refractive index dielectric film has a refractive index of from about 1.5 to about 1.8.

22. The lighting device of claim 19 wherein the nanoporous organosilicate film comprises a low refractive index nanoporous film having a refractive index of from about 1.05 to about 1.4, and, which low refractive index nanoporous film is present on an opposite surface of the substrate than the high refractive index dielectric film.

23. The transparent article of claim 11 wherein the substrate comprises an array of metal lines, and wherein the nanoporous organosilicate film is positioned between the lines and optionally on the lines.

24. The transparent article of claim 11 wherein the substrate comprises a light emitting or light transmitting layer; an epitaxial layer on the light emitting or light transmitting layer, which epitaxial layer comprises a doping amount of n-type or p-type doping material in at least an uppermost portion of the epitaxial layer; and an array of metal lines through the epitaxial layer; wherein the nanoporous organosilicate film is positioned on the epitaxial layer and on the array of metal lines.

25. The transparent article of claim 24 wherein the light emitting or light transmitting layer comprises sapphire and the epitaxial layer comprises aluminum oxide, silicon carbide, gallium nitride, indium gallium phosphide, indium gallium arsenide, indium tin oxide or combinations thereof.

26. The transparent article of claim 11 wherein the substrate comprises a light emitting or light transmitting layer; an array of light emitting transistors or phosphors on the light emitting or light transmitting layer; an organic light emitting material on and between the array of light emitting transistors or phosphors; wherein the nanoporous organosilicate film is positioned on the organic light emitting material.

27. The transparent article of claim 11 wherein the substrate comprises sequentially: a first light emitting or light transmitting layer; a first electrode on the first light emitting or light transmitting layer; an organic light emitting material on the first electrode; a second electrode on the organic light emitting material; and second light emitting or light transmitting layer on the second electrode; wherein the nanoporous organosilicate film is positioned on the first light emitting or light transmitting layer.

28. The transparent article of claim 27 further comprising a light reflecting or light absorbing material positioned around a perimeter of the first light emitting or light transmitting layer, between the first light emitting or light transmitting layer and the nanoporous organosilicate film.

29. The transparent article of claim 27 further comprising a second nanoporous organosilicate film positioned on the second light emitting or light transmitting layer.

30. The transparent article of claim 29 further comprising a light reflecting or light absorbing material positioned around a perimeter of the first light emitting or light transmitting layer, between the first light emitting or light transmitting layer and the nanoporous organosilicate film; and second light reflecting or light absorbing material positioned around a perimeter of the second light emitting or light transmitting layer between the second light emitting or light transmitting layer and the second nanoporous organosilicate film.
